(19) United States
(12) Patent Application Publication
(10) Pub. No.: US 2026/0271209 A1
(43) Pub. Date: Sep. 10, 2026

(54) SERVER

(71) Applicant: Fulian Percision Electronics (Tianjin) Co., LTD., Tianjin (CN)

(72) Inventors: TUNG-HO SHIH, New Taipei (TW); Ying-Jie Huang, New Taipei (TW)

(21) Appl. No.: 19/171,528

(22) Filed: Apr. 7, 2025

(30) Foreign Application Priority Data
Mar. 4, 2025 (CN) 202510249702.1

(51) Int. Cl. H05K 7/14

(52) U.S. Cl. CPC H05K 7/1404; H05K 7/1487

(57) ABSTRACT

A server includes a base assembly, a connector, and a housing. A base assembly includes a base plate, a first structural member, and a first clamping member fixed to each other. The first clamping member protrudes from the first structural member. The first structural member includes an elastic portion and a protrusion. The protrusion is located at an end of the elastic portion. The connector is disposed on the base plate. The housing includes a housing portion and a pressing portion. The housing portion defines a sliding groove and a first slot. Wherein the first clamping member can move along the first slot and engages with the sliding groove, the protrusion can engage with the first slot, and the pressing portion is located at a side of the connector away from the base plate.

### FIELD

The subject matter herein generally relates to terminal technologies, and more particularly, to a server.

### BACKGROUND

A server includes a base, a server body, and a connector. The connector is connected to the server body for establishing signal communication with external devices. Screws may be used to fix the connector to the base. When the connector needs to be disassembled from or installed onto the base, tools are required for rotating the screws, which increases time and labor costs. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view of a server according to an embodiment of the present disclosure.

FIG. 2 is an exploded view of the server shown in FIG. 1.

FIG. 3 is similar to FIG. 2, but showing the server viewed from another angle.

FIG. 4 is a diagrammatic view showing a force applied to a third structural member of the server shown in FIG. 1.

FIG. 5 is a diagrammatic view showing a force applied to a second structural member of the server shown in FIG. 4.

FIG. 6 is a diagrammatic view showing a removal process of a server body of the server shown in FIG. 5.

FIG. 7 is a diagrammatic view showing a movement of a housing and the removal process of the connector of the server shown in FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

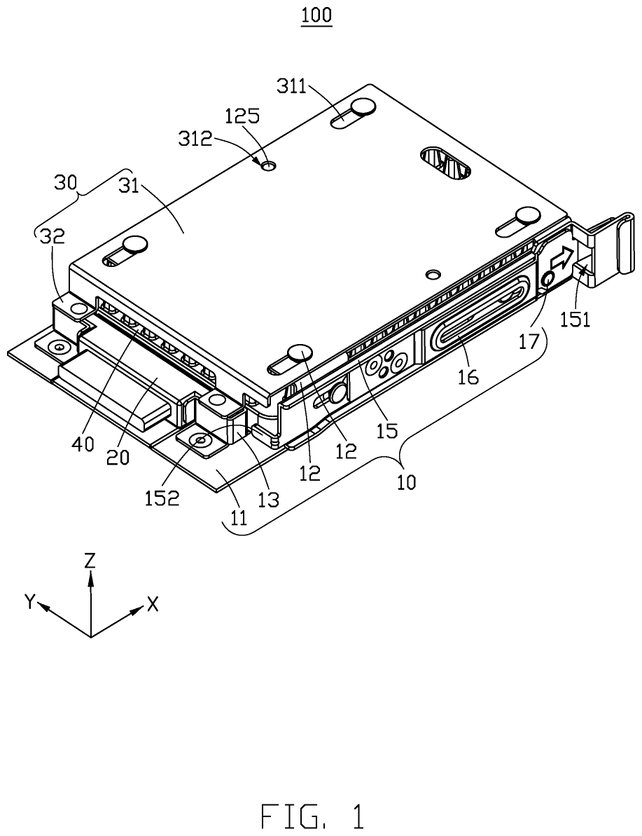

Referring to FIG. 1, a server 100 is provided according to an embodiment of the present disclosure. The server 100 may include a base assembly 10, a connector 20, a server body 40, and a housing 30. The housing 30 is detachably fixed to the base assembly 10. The server body 40 is located between the base assembly 10 and the housing 30. The connector 20 is inserted into the server body 40 and positioned between the base assembly 10 and the housing 30. The connector 20 can be disassembled from the server body 40 without additional tools.

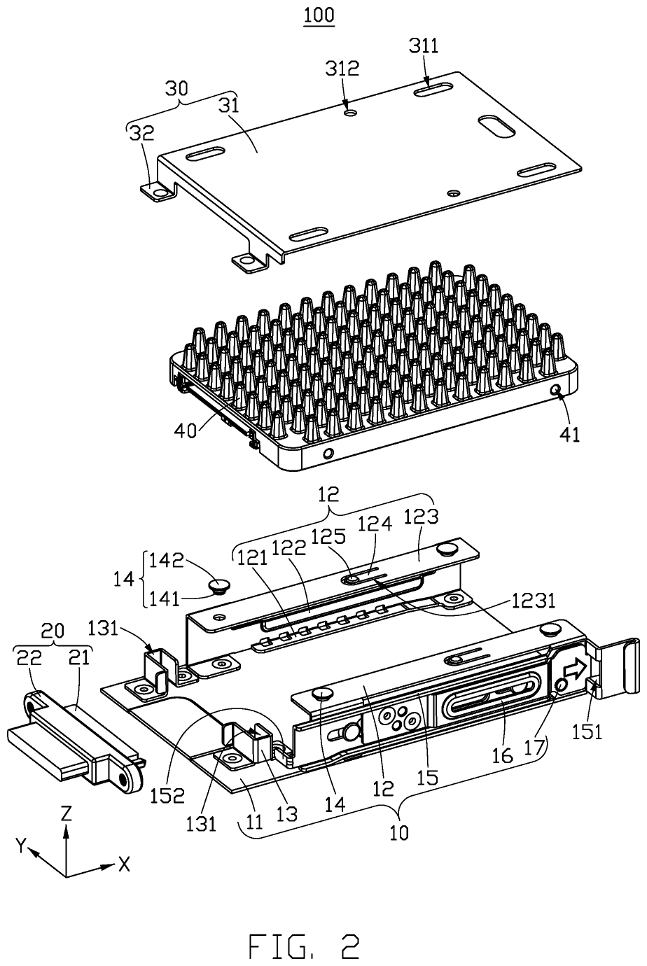

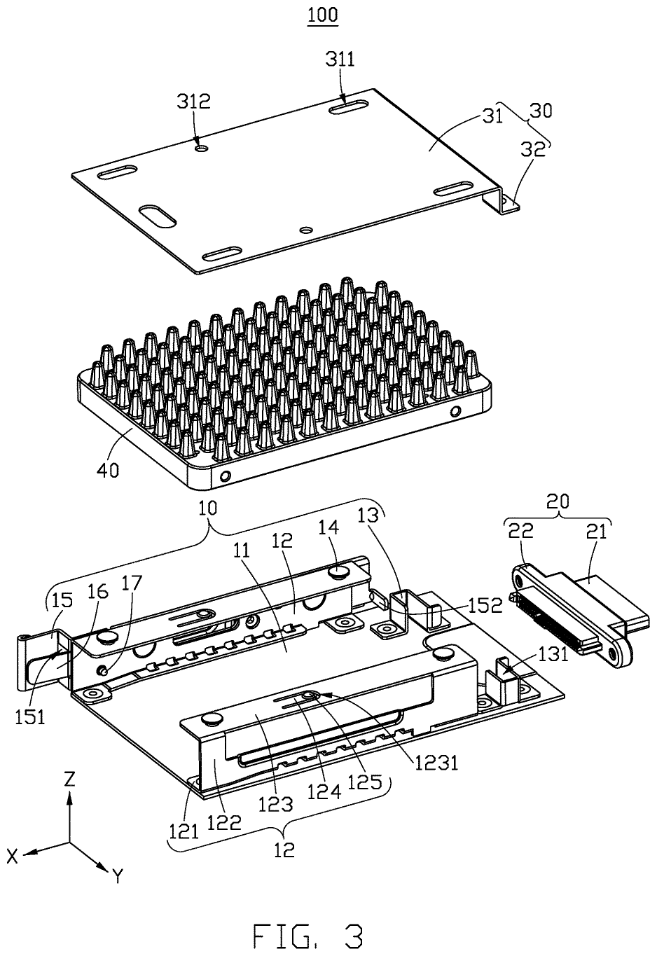

Referring to FIGS. 2 and 3, the base assembly 10 may include a base plate 11, a first structural member 12, a first clamping member 14, and a bracket 13. The base plate 11, the first structural member 12, the first clamping member 14, and the bracket 13 are fixed relative to each other. In the embodiment, the first structural member 12 is detachably fixed to the base plate 11, the bracket 13 is detachably fixed to the first structural member 12, and the first clamping member 14 is detachably fixed to the first structural member 12. In other embodiments, the first structural member 12 and the base plate 11 may be integrally formed, the bracket 13 and the base plate 11 may be integrally formed, and the first clamping member 14 and the first structural member 12 may be integrally formed. For ease of description, a three-dimensional coordinate system is defined, wherein two of the X-axis direction, Y-axis direction and Z-axis direction may be perpendicular to each other.

The base plate 11 is substantially a rectangular plate, and the base plate 11 is perpendicular to the Z-axis direction. The base assembly 10 includes two first structural members 12. The two first structural members 12 are located on a same surface of the base plate 11 and located on both sides of the base plate 11. The two first structural members 12 are disposed along the Z-axis direction with the base plate 11. The two first structural members 12 are disposed along the Y-axis direction. Each first structural member 12 is substantially C-shaped along a cross-section perpendicular to the X-axis direction. The two first structural members 12 are opposite to each other. The base plate 11 and the two first structural members 12 form an accommodating space (not shown), and the server body 40 is disposed on the base plate 11 and located in the accommodating space.

Each first structural member 12 may include a fixing portion 121, a connecting portion 122, a main body 123, an elastic portion 124, and a protrusion 125. The connecting portion 122 is connected to the fixing portion 121 and the main body 123. The fixing portion 121 and the main body 123 are located on both sides of the connecting portion 122. The fixing portion 121 and the main body 123 are disposed along the Z-axis direction and spaced apart from each other. The fixing portion 121 can be fixed to the base plate 11. The elastic portion 124 is elastically connected to the main body 123. The protrusion 125 is located at the end of the elastic portion 124 and on the surface of the elastic portion 124 away from the fixing portion 121.

A groove 1231 is defined on the main body 123. The groove 1231 is substantially U-shaped. The elastic portion 124 is located in the groove 1231. One end of the elastic portion 124 is connected to the main body 123, and another end of the elastic portion 124 is spaced apart from the main body 123. The protrusion 125 is located at the other end of the elastic portion 124 away from the main body 123, and the elastic portion 124 can move relative to the main body 123 along the Z-axis direction, thereby driving the protrusion 125 to move synchronously.

The first clamping member 14 is disposed on the first structural member 12, and the first clamping member 14 protrudes from the main body 123. The first clamping member 14 may include a clamping portion 141 and a protruding portion 142. The clamping portion 141 is substantially columnar, and the clamping portion 141 is fixed to the main body 123. The protruding portion 142 is located at the end of the clamping portion 141 away from the clamping portion 141. The protruding portion 142 and the main body 123 are spaced apart from each other. An orthogonal projection of the protruding portion 142 on the main body 123 entirely covers an orthogonal projection of the clamping portion 141 on the main body 123.

In the embodiment, the base assembly 10 includes four first clamping members 14, with two first clamping members 14 being fixed on each main body 123.

The housing 30 includes a housing portion 31 and a pressing portion 32 connected to each other. The pressing portion 32 is located at an end of the housing portion 31. The housing portion 31 can be detachably connected to the main body 123. A sliding groove 311 and a first slot 312 are defined on the housing portion 31. The housing portion 31 can move relative to the first structural member 12 along the X-axis, with the pressing portion 32 moving synchronously with the housing portion 31.

The first clamping member 14 can move in the sliding groove 311, allowing the protrusion 125 to move relative to the housing portion 31 until the protrusion 125 engages with the first slot 312, thereby fixing the housing 30 and the first structural member 12 together. When the protrusion 125 engages with the first slot 312, the housing portion 31 is located between the protruding portion 142 and the main body 123.

The clamping portion 141 extends through the housing portion 31 via the sliding groove 311. When the first clamping member 14 moves along the X-axis direction, the first clamping member 14 moves in the sliding groove 311 from one end to the other end until the protruding portion 142 engages with the first slot 312. During the movement of the housing 30 relative to the first clamping member 14, the protruding portion 142 abuts against the housing portion 31 until the protruding portion 142 aligns with the first slot 312, and under the elastic force of the elastic portion 124, the protruding portion 142 is driven to engage with the first slot 312.

The bracket 13 and the first structural member 12 are disposed on the same surface of the base plate 11. The bracket 13 is located between the base plate 11 and the pressing portion 32. In the embodiment, the server 100 includes two brackets 13. The two brackets 13 are disposed on the same surface of the base plate 11 and spaced apart from each other along the Y-axis direction. Each bracket 13 has an accommodating cavity 131. The two accommodating cavities 131 are opposite to each other, and the two accommodating cavities 131 can accommodate both ends of the connector 20. In other embodiments, the server 100 may include one bracket 13 with one accommodating cavity 131, where the connector 20 is accommodated in the accommodating cavity 131.

The connector 20 includes an inserting portion 21 and two limiting portions 22. The two limiting portions 22 are located on both sides of the inserting portion 21. The inserting portion 21 is exposed from the bracket 13 and can be inserted into the server body 40 to establish electrical connection. The limiting portions 22 are located in the accommodating cavity 131. The pressing portion 32 is located at a side of the limiting portions 22 away from the base plate 11 and can limit the position of the connector 20.

The base assembly 10 further includes a second structural member 15 and a third structural member 16. The second structural member 15 and the third structural member 16 extend substantially along the X-axis direction. The second structural member 15 is movably connected to the connecting portion 122 and can move relative to the connecting portion 122 along the X-axis direction. The third structural member 16 is fixed to a side of the second structural member 15 away from the connecting portion 122, and the third structural member 16 can move synchronously with the second structural member 15. A second slot 151 is defined on one end portion of the second structural member 15. The other end portion of the second structural member 15 is provided with a hook portion 152 located at an end of the server body 40, and an end of the third structural member 16 extends through the second slot 151.

The base assembly 10 further includes a second clamping member 17 fixed to the third structural member 16. The connecting portion 122 is provided with a first through hole (not labeled), an end of the second structural member 15 is provided with a second through hole (not shown), the third structural member 16 is provided with a third through hole (not labeled), and the server body 40 is provided with a third slot 41. The second clamping member 17 extends through the third through hole, the second through hole, the first through hole, and extends to the third slot 41 in sequence, and the second clamping member 17 is configured to limit the server body 40.

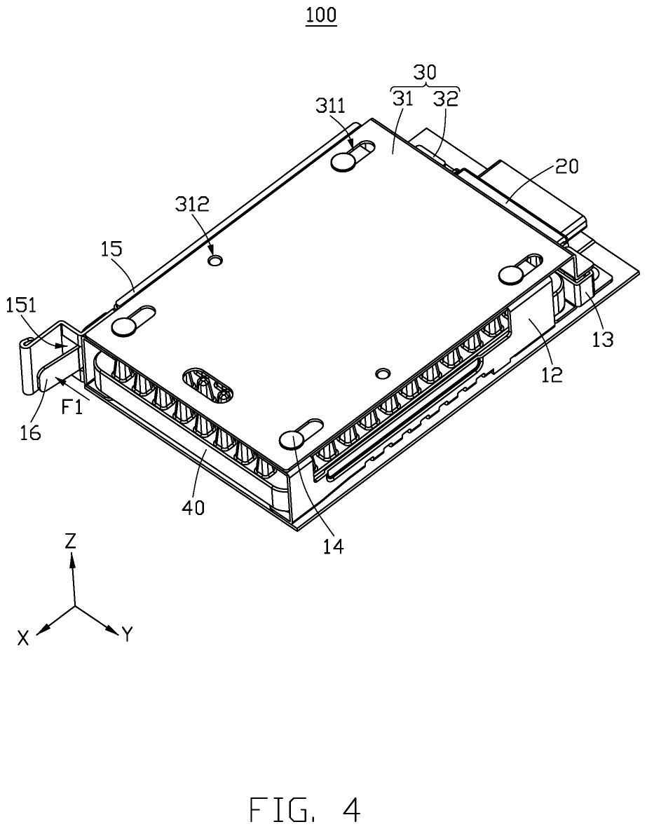

Referring to FIGS. 4 to 7, which show a process of disassembling the connector 20 from the server body 40.

Referring to FIG. 4, when a force F1 is applied to the third structural member 16 along the Y-axis direction and away from the server body 40, the end of the third structural member 16 moves in the direction away from the server body 40, and the second clamping member 17 withdraws from the third slot 41 (referring to FIG. 3), thereby releasing the server body 40.

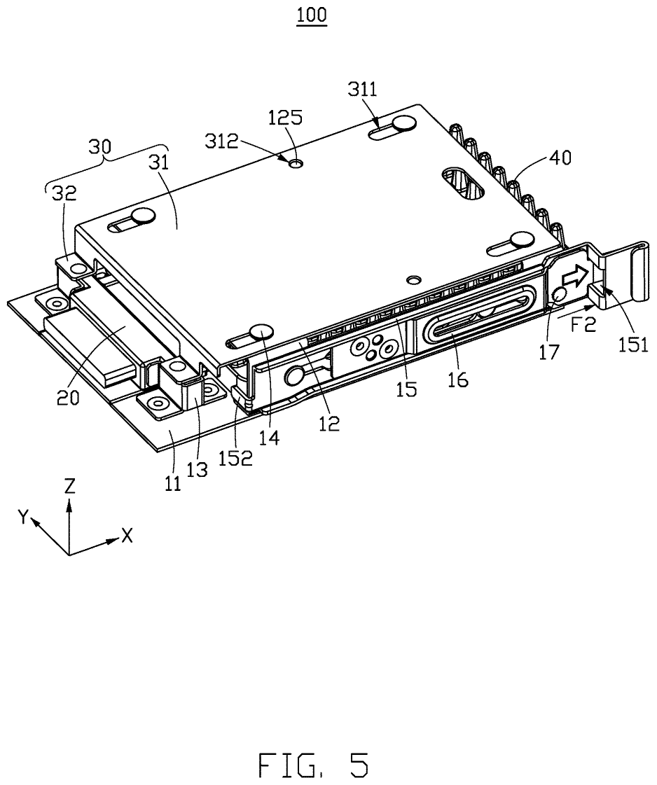

Referring to FIG. 5, when a force F2 is applied to the second structural member 15 along the X-axis direction and away from the connector 20, the second structural member 15 and the third structural member 16 move along the X-axis direction. At this time, the hook portion 152 of the second structural member 15 drives the server body 40 to move synchronously, thereby separating the server body 40 from the connector 20.

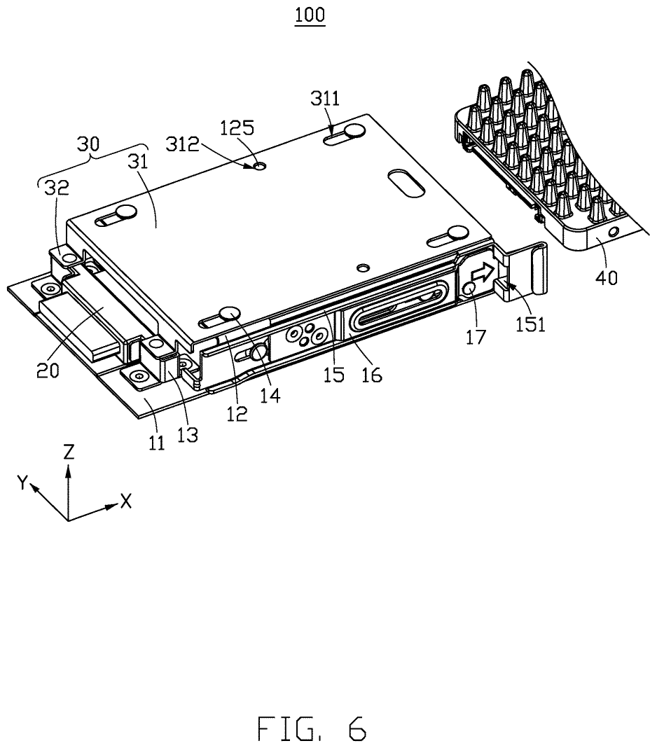

Referring to FIG. 6, the server body 40 is taken out, and the second structural member 15 and the third structural member 16 return to their initial positions.

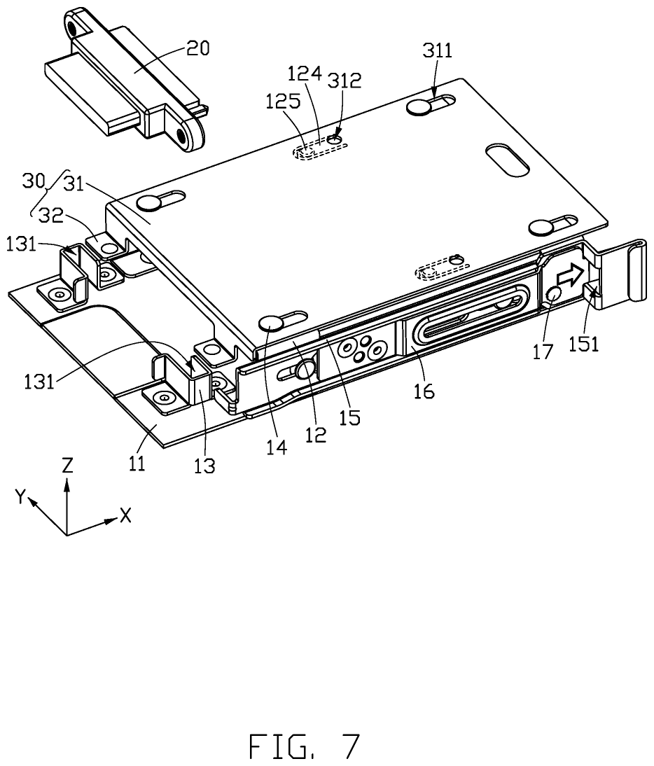

Referring to FIG. 7, when a force F3 is applied to the housing 30 along the X-axis direction and away from the connector 20, the housing 30 moves relative to the first structural member 12 along the X-axis direction. During the movement of the housing 30, the protrusion 125 gradually withdraws from the first slot 312, and the first structural member 12 releases the housing 30. At this time, the pressing portion 32 moves along the X-axis direction to expose the limiting portions 22, and the pressing portion 32 releases the limiting portions 22, thereby realizing the removal of the connector 20 without additional tools.

It should be noted that in the embodiment, when disassembling the connector 20, since the server body 40 interferes with the position of the housing 30, the server body 40 needs to be removed first. In other embodiments, if the server body 40 does not interfere with the process of disassembling the connector 20, there is no need to remove the server body 40.

When it is needed to install the connector 20, the server body 40 is first fixed in the base assembly 10, then the connector 20 is placed on the base plate 11, with the inserting portion 21 being inserted into the server body 40 and the limiting portions 22 being located in the accommodating cavity 131. The housing 30 is moved towards the direction of the connector 20 until the protrusion 125 engages with the first slot 312, and the pressing portion 32 is located at a side of the limiting portions 22 away from the base plate 11, thereby limiting the position of the connector 20.

The server 100 provided by the embodiment of the present disclosure allows the disassembly and installation of the connector 20 without additional tools, thereby reducing time and labor costs. The server 100 does not require any space for operating the screws to fix the connector 20, thereby improving space utilization.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A server comprising:
a base assembly comprising a base plate, a first structural member, and a first clamping member fixed to each other, the first clamping member protruding from the first structural member, the first structural member comprising an elastic portion and a protrusion located at an end of the elastic portion;
a connector disposed on the base plate; and
a housing comprising a housing portion and a pressing portion connected to each other, the housing portion defining a sliding groove and a first slot;
wherein the first clamping member is configured to move along the first slot and engages with the sliding groove, the protrusion is configured to engages with the first slot, and the pressing portion is located at a side of the connector away from the base plate.

2. The server of claim 1, wherein the base assembly further comprises a bracket disposed on the base plate, the bracket defines an accommodating cavity; at least a portion of the connector is accommodated in the accommodating cavity, and the pressing portion is located at a side of the bracket away from the base plate.

3. The server of claim 2, wherein the connector comprises an inserting portion and a limiting portion, the limiting portion is located in the accommodating cavity, and the inserting portion is exposed from the bracket.

4. The server of claim 3, further comprising a server body disposed on the base plate, wherein the inserting portion is inserted into the server body.

5. The server of claim 1, wherein the base assembly further comprises two brackets disposed on the base plate and spaced from each other, each of the two brackets defines an accommodating cavity; each of two ends of the connector is accommodated in the accommodating cavity of a respective bracket of the two brackets, and the pressing portion is located at a side of the two brackets away from the base plate.

6. The server of claim 5, wherein the connector comprises an inserting portion and two limiting portions, one of the two limiting portions is located in the accommodating cavity of the respective bracket, and the inserting portion is exposed from the respective bracket.

7. The server of claim 1, wherein the first structural member further comprises a main body, the elastic portion is elastically connected to the main body, and the first clamping member is fixed to the main body.

8. The server of claim 7, wherein the main body defines a groove, the elastic portion is located in the groove, one end of the elastic portion is connected to the main body, another end of the elastic portion is spaced apart from the main body, and the protrusion is located at the other end of the elastic portion away from the main body.

9. The server of claim 8, wherein the first structural member further comprises a fixing portion and a connecting portion, the connecting portion is connected to the fixing portion and the main body, the fixing portion is fixed to the base plate, and the main body and the fixing portion are spaced apart from each other.

10. The server of claim 9, further comprising a server body, wherein the base assembly further comprises a second structural member and a third structural member, the third structural member is fixed to a side of the second structural member away from the connecting portion, and the server body is disposed on the base plate.

11. The server of claim 10, wherein one end portion of the second structural member defines a second slot, another end portion of the second structural member is provided with a hook portion, the hook portion is located at an end of the server body, and an end of the third structural member extends through the second slot.

12. The server of claim 11, wherein the base assembly further comprises a second clamping member, the server body defines a third slot, the second clamping member is fixed to the third structural member, and the second clamping member extends through the second structural member and the connecting portion to the third slot.

13. The server of claim 2, wherein the first structural member further comprises a main body, the elastic portion is elastically connected to the main body, and the first clamping member is fixed to the main body.

14. The server of claim 3, wherein the first structural member further comprises a main body, the elastic portion is elastically connected to the main body, and the first clamping member is fixed to the main body.

15. The server of claim 4, wherein the first structural member further comprises a main body, the elastic portion is elastically connected to the main body, and the first clamping member is fixed to the main body.

16. The server of claim 2, wherein the first clamping member comprises a clamping portion and a protruding portion, the clamping portion is fixed to the main body, the protruding portion and the main body are spaced apart from each other, and the housing portion is located between the protruding portion and the main body.

17. The server of claim 16, wherein an orthogonal projection of the protruding portion on the main body entirely covers an orthogonal projection of the clamping portion on the main body.

18. The server of claim 3, wherein the first clamping member comprises a clamping portion and a protruding portion, the clamping portion is fixed to the main body, the protruding portion and the main body are spaced apart from each other, and the housing portion is located between the protruding portion and the main body.

19. The server of claim 4, wherein the first clamping member comprises a clamping portion and a protruding portion, the clamping portion is fixed to the main body, the protruding portion and the main body are spaced apart from each other, and the housing portion is located between the protruding portion and the main body.

20. The server of claim 5, wherein the first clamping member comprises a clamping portion and a protruding portion, the clamping portion is fixed to the main body, the protruding portion and the main body are spaced apart from each other, and the housing portion is located between the protruding portion and the main body.
